(19) United States
(12) Patent Application Publication
(10) Pub. No.: US 2026/0181871 A1
(43) Pub. Date: Jun. 25, 2026

(54) MEMORY DEVICE AND METHOD FOR MANUFACTURING THE SAME

(71) Applicant: SK hynix Inc., Gyeonggi-do (KR)

(72) Inventor: Heon Yong CHANG, Gyeonggi-do (KR)

(21) Appl. No.: 19/185,253

(22) Filed: Apr. 22, 2025

(30) Foreign Application Priority Data
Dec. 19, 2024 (KR) 10-2024-0190921

(51) Int. Cl. H10B 12/00

(52) U.S. Cl. CPC H10B 12/482; H10B 12/02; H10B 12/315

(57) ABSTRACT

A memory device may include a substrate, bit lines disposed on the substrate, extending in a first direction of an upper surface of the substrate, and spaced apart from each other in a second direction of the upper surface of the substrate, an interlayer insulation layer disposed between the bit lines, and channel structures respectively connected to the bit lines and extending in a third direction perpendicular to the upper surface of the substrate. Each of the bit lines may include a conductive layer and a barrier layer surrounding a side surface and an upper surface of the conductive layer.

### CROSS-REFERENCES TO RELATED APPLICATION

The present application claims priority under 35 U.S.C. 119(a) to Korean patent application number 10-2024-0190921 filed on Dec. 19, 2024, which is incorporated herein by reference in its entirety.

### TECHNICAL FIELD

Embodiments of the present disclosure relate generally to semiconductor technology, and more particularly to a memory device and a method for manufacturing the same.

### BACKGROUND

By their miniaturization, multi-functionality, and/or low manufacturing cost characteristics, memory devices are attracting attention as an important element in the electronics industry. As the electronics industry advances, memory devices are becoming increasingly highly integrated. For highly integrated memory devices, the width of the lines included in the memory device is gradually decreasing, increasing the difficulty in forming the memory device.

### SUMMARY

Embodiments of the present disclosure provide a memory device and a method for manufacturing the same capable of preventing a short circuit between adjacent lines.

Embodiments of the present disclosure are not limited to those set forth herein, and other unmentioned embodiments would be apparent to one of ordinary skill in the art from the following description.

Embodiments of the present disclosure provide a memory device comprising a substrate having an upper surface, bit lines disposed on the substrate, an interlayer insulation layer disposed between the bit lines, and channel structures respectively connected to the bit lines, wherein the bit lines are extending in a first direction of the upper surface of the substrate, wherein the bit lines are spaced apart from each other in a second direction of the upper surface of the substrate, wherein each of the bit lines includes a conductive layer and a barrier layer surrounding a side surface and an upper surface of the conductive layer, and wherein each of the channel structures is extending in a third direction perpendicular to the upper surface of the substrate.

Embodiments of the present disclosure provide a memory device comprising a first semiconductor structure and a bonding insulation layer disposed on the first semiconductor structure, and a second semiconductor structure disposed on the bonding insulation layer, wherein the second semiconductor structure includes bit lines extending in a first direction of an upper surface of the first semiconductor structure, spaced apart from each other in a second direction of the upper surface of the first semiconductor structure, and including a conductive layer and a barrier layer surrounding a side surface and an upper surface of the conductive layer and an interlayer insulation layer disposed between the bit lines and spaced apart from the conductive layer in the second direction.

Embodiments of the present disclosure provide a method for manufacturing a memory device comprising forming, on a first substrate, a channel structure extending in a direction perpendicular to the first substrate, forming an interlayer insulation material layer on the channel structure, forming first holes in the interlayer insulation material layer in an area overlapping the channel structure, and forming bit lines in the first holes.

According to embodiments of the present disclosure, there are provided a memory device and a method for manufacturing the same capable of preventing a short circuit occurring between adjacent lines.

The advantageous effects of the embodiments of the present disclosure are not limited to the foregoing advantages, and other advantageous effects will be apparent to one of ordinary skill in the art from the following detailed description.

### BRIEF DESCRIPTION OF THE DRAWINGS

The embodiments of the present disclosure will be more fully understood from the following detailed description and the accompanying drawings, which are provided for illustration only and are not intended to limit the embodiments.

FIG. 1 is a view illustrating a planar structure of a memory device according to embodiments of the present disclosure.

FIGS. 2 and 3 are views illustrating a cross-sectional structure of a memory device according to embodiments of the present disclosure.

FIG. 4 is an enlarged view of portion 10 of FIG. 3.

FIGS. 5 and 6 are views illustrating another cross-sectional structure of a memory device according to embodiments of the present disclosure.

FIGS. 7 to 17 are views illustrating a method for forming a memory device according to embodiments of the present disclosure.

FIGS. 18 to 21 are views illustrating another method for forming a memory device according to embodiments of the present disclosure.

### DETAIL DESCRIPTION

Hereinafter, embodiments of the present disclosure are described in detail with reference to the accompanying drawings. In assigning reference numerals to components of each drawing, the same components may be assigned the same numerals even when they are shown on different drawings. When it is determined that the subject matter of the present disclosure may be unclear, the details of the known art or functions may be skipped. As used herein, when a component “includes,” “has,” or “is composed of” another component, the component may have other components unless the term “only” is used with “includes, has, or is composed of”. As used herein, the singular forms “a”, “an” and “the” are intended to include the plural forms as well, unless the context clearly indicates otherwise.

Such labels as “first,” “second,” “A,” “B,” “(a),” and “(b),” may be used in describing the components of the present disclosure. These labels are provided merely to distinguish a component from another, and the essence, order, or number of the components are not limited by the labels.

In describing the positional relationship between components, when two or more components are described as “connected”, “coupled” or “linked”, the two or more components may be directly “connected”, “coupled” or “linked” “, or another component may intervene. Here, the other component may be included in one or more of the two or more components that are “connected”, “coupled” or “linked” to each other.

When such terms as, e.g., “after”, “next to”, and “before”, are used to describe the temporal flow relationship related to components, operation methods, and fabricating methods, it may include a non-continuous relationship unless the term “immediately” or “directly” is used with “after”, “next to”, and “before”.

When a component is designated with a value or its corresponding information (e.g., level), the value or the corresponding information may be interpreted as including a tolerance that may arise due to various factors (e.g., process factors, internal or external impacts, or noise).

In the accompanying drawings, the directions of the upper surface of the substrate are defined as a first direction FD and a second direction SD, respectively, and the direction protruding vertically from the upper surface of the substrate is defined as a third direction VD. The first direction FD and the second direction SD may be substantially perpendicular to each other. The third direction VD is a direction perpendicular to the first direction FD and the second direction SD. In the following specification, ‘vertical’ or ‘vertical direction’ will be used as having the same or substantially the same meaning as the third direction VD. The direction indicated by arrow in the drawings and the opposite direction indicate the same direction.

Hereinafter, various embodiments of the present disclosure will be described in detail with reference to accompanying drawings.

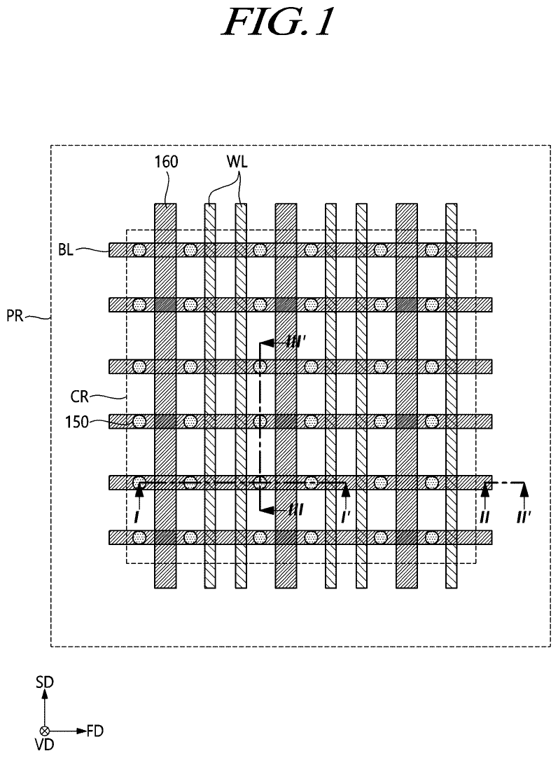

FIG. 1 is a view illustrating a planar structure of a memory device according to embodiments of the present disclosure.

Referring to FIG. 1, a memory device according to embodiments of the present disclosure includes a cell area CR and a peripheral area PR. The cell area CR is an area in which memory cells are disposed. The peripheral area PR is an area in which peripheral circuits transferring various signals and voltages to the memory cells are disposed. The peripheral area PR is disposed around the cell area CR. In an embodiment, the peripheral area PR may surround the cell area CR.

The memory device includes a bit line BL, a word line WL, a back gate electrode 160, and a channel structure 150.

The bit line BL may extend in the first direction FD. The bit line BL crosses the back gate electrode 160 and the word line WL. The bit line BL may extend from the cell area CR to the peripheral area PR. The back gate electrode 160 and the word line WL may extend in the second direction SD. The back gate electrode 160 and the word line WL cross the bit line BL. The back gate electrode 160 and the word line WL may extend from the cell area CR to the peripheral area PR.

In an embodiment, each of the back gate electrode 160 and the word line WL may be substantially perpendicular to the bit line BL. In an embodiment, two word lines WL may be disposed between the adjacent back gate electrodes 160.

The channel structure 150 overlaps the bit line BL. An upper surface or a lower surface of the channel structure 150 may be circular. However, the shape of the upper surface or the lower surface of the channel structure 150 is not limited thereto. In an embodiment, the width in the second direction SD of the upper surface or the lower surface of the channel structure 150 may be thinner than the width in the second direction SD of the bit line BL. Alternatively, in another embodiment, the width in the second direction SD of the upper or lower surface of the channel structure 150 may be wider than the width in the second direction SD of the bit line BL. In an embodiment, the channel structure 150 may be positioned between the word line WL and the back gate electrode 160.

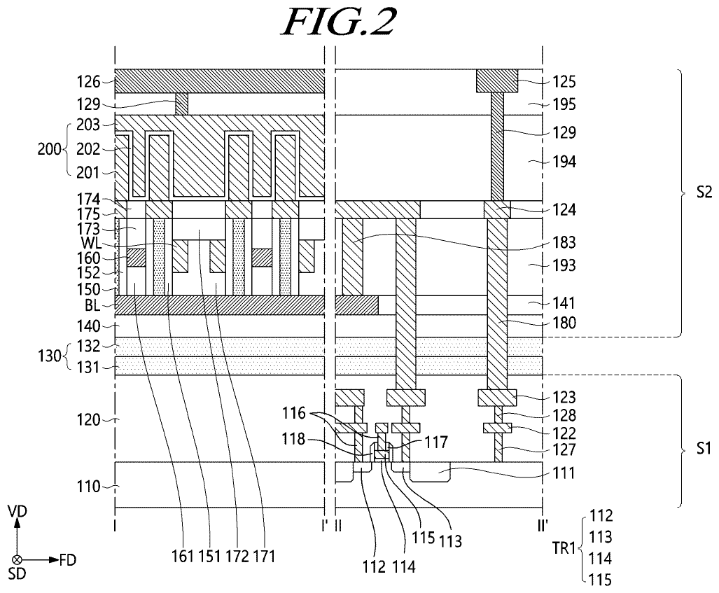

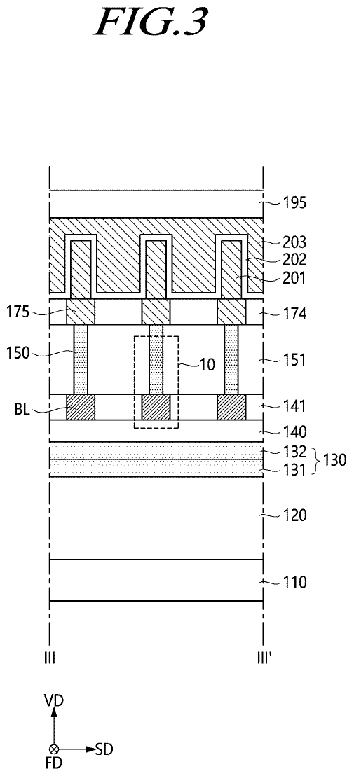

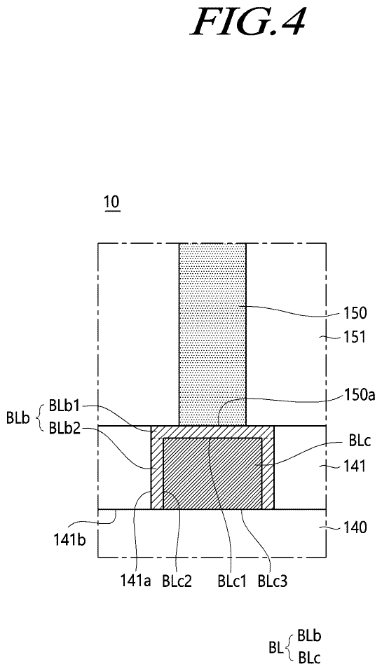

FIGS. 2 and 3 are views illustrating a cross-sectional structure of a memory device according to embodiments of the present disclosure. FIG. 4 is an enlarged view of portion 10 of FIG. 3.

Referring to FIG. 2, a memory device according to embodiments of the present disclosure includes a first semiconductor structure S1, a second semiconductor structure S2, a bonding insulation layer 130, and a contact plug 180.

The first semiconductor structure S1 includes a substrate 110,

an element isolation layer 111, a lower transistor TR1, a gate capping layer 117, a spacer 118, a first insulation layer 120, lines 122 and 123, and contacts 116, 127, and 128.

The second semiconductor structure S2 includes a second insulation layer 140, an interlayer insulation layer 141, a bit line BL, a channel structure 150, a second gate insulation layer 151, a third gate insulation layer 152, a back gate electrode 160, a back gate capping layer 161, a first insulation pattern 171, a second insulation pattern 172, a third insulation pattern 173, a fourth insulation pattern 174, a word line WL, a landing pad 175, lines 124, 125, and 126, a fourth contact 129, a third insulation layer 193, a fourth insulation layer 194, a fifth insulation layer 195, and a capacitor 200.

The bonding insulation layer 130 includes a first bonding insulation layer 131 and a second bonding insulation layer 132.

The lower transistor TR1 includes a source area 112, a drain area 113, a first gate insulation layer 114, and a gate electrode layer 115. The capacitor 200 includes a lower electrode 201, a dielectric layer 202, and an upper electrode 203.

The substrate 110 may include a semiconductor substrate such as a silicon wafer or a silicon on insulator (SOI) wafer. The substrate 110 may include a group III-V semiconductor substrate, e.g., a compound semiconductor substrate such as GaAs. The substrate 110 may include monocrystalline silicon, polysilicon, amorphous silicon, monocrystalline silicon germanium, polycrystalline silicon germanium, carbon-doped silicon, or a combination thereof.

At least one element isolation layer 111 is disposed in the substrate 110. The element isolation layer 111 may be formed using a trench element isolation technology such as shallow trench isolation (STI). The element isolation layer 111 may include silicon oxide, silicon nitride, silicon oxynitride, low-K dielectrics, high-K dielectrics, or a combination thereof.

The lower transistor TR1 is disposed on the substrate 110. In an embodiment, the lower transistor TR1 may be any of transistors included in the peripheral circuit. The first contact 116 is connected to the source area 112 and the drain area 113 of the lower transistor TR1 formed in the substrate 110. The second contact 127, the first line 122, the third contact 128, and the second line 123 may be sequentially disposed on the substrate 110 in an area other than the area in which the lower transistor TR1 is disposed. The first line 122 may be connected to the first contact 116 and the second contact 127. The second line 123 may be connected to the third contact 128. The first insulation layer 120 is disposed to cover the lower transistor TR1, the first contact 116, the second contact 127, the first line 122, the third contact 128, and the second line 123.

The second line 123 may be referred to as a lower line. The second line 123 may be connected to the drain area 113 of the lower transistor TR1 through the first contact 116, the first line 122, and the third contact 128.

The first bonding insulation layer 131 is disposed on the first semiconductor structure S1. The first bonding insulation layer 131 is disposed between the first semiconductor structure S1 and the second semiconductor structure S2. The second bonding insulation layer 132 is disposed under the second semiconductor structure S2. The second bonding insulation layer 132 is disposed between the first bonding insulation layer 131 and the second semiconductor structure S2.

The first gate insulation layer 114 and the first insulation layer 120 may include silicon oxide, silicon nitride, silicon oxynitride, high-K dielectric, or a combination thereof. The gate electrode 115, the first contact 116, the second contact 127, the first line 122, the third contact 128, and the second line 123 may include a conductive material such as metal, metal oxide, metal nitride, metal silicide, polysilicon, conductive carbon, or a combination thereof. The bonding insulation layer 130 may include silicon oxide, silicon nitride, silicon oxynitride, silicon carbonitride, high-K dielectric, or a combination thereof.

A second semiconductor structure S2 is disposed on the second bonding insulation layer 132. The second semiconductor structure S2 may be bonded to the first semiconductor structure S1 through a bonding insulation layer 130.

The second insulation layer 140 is disposed on the second bonding insulation layer 132. The bit line BL and the interlayer insulation layer 141 are disposed on the second insulation layer 140. The bit line BL extends along the first direction FD. The second insulation layer 140 and the interlayer insulation layer 141 may include silicon oxide, silicon nitride, silicon oxynitride, silicon carbonitride, a high-K dielectric, or a combination thereof. The bit line BL may include a conductive material such as metal, metal nitride, metal silicide, polysilicon, conductive carbon, or a combination thereof. In an embodiment, the interlayer insulation layer 141 may include oxide.

The memory cells are disposed on the bit lines BL. In an embodiment, the memory cell may include one transistor and one capacitor. Hereinafter, an embodiment in which the memory cell includes one transistor and one capacitor is described however other numbers of transistors and capacitors may be used.

The channel structure 150 contacts the upper surface of the bit line BL and extends in the vertical direction. The channel structure 150 may include a channel area formed in an area overlapping the word line WL in the first direction FD. The channel structure 150 may include a source or drain area formed above or below the channel area. For example, the source area may be formed above the channel area in the channel structure 150, and the drain area may be formed below the channel area in the channel structure 150. The channel structure 150 may include polysilicon or single crystalline silicon.

A second gate insulation layer 151 and a third gate insulation layer 152 are disposed on a side surface of the channel structure 150. The second gate insulation layer 151 is disposed between the channel structure 150 and the word line WL. The second gate insulation layer 151 extends in a vertical direction. The third gate insulation layer 152 is disposed between the channel structure 150 and the back gate electrode 160. The third gate insulation layer 152 extends in a vertical direction. The second gate insulation layer 151 and the third gate insulation layer 152 may include silicon oxide, silicon nitride, silicon oxynitride, silicon carbonitride, a high-K dielectric, or a combination thereof.

The word line WL, the first insulation pattern 171, and the second insulation pattern 172 are disposed between the second gate insulation layers 151 facing each other. The length of the word line WL in the vertical direction may be shorter than the length of the channel structure 150 in the vertical direction. The first insulation pattern 171 is positioned between the word lines WL facing each other. The first insulation pattern 171 may cover one side surface and a lower surface of the word line WL. The second insulation pattern 172 may cover an upper surface of the first insulation pattern 171 and the word line WL.

The back gate electrode 160, the second gate capping layer 161, and the third insulation pattern 173 are disposed between the third gate insulation layers 152 facing each other. The length of the back gate electrode 160 in the vertical direction may be shorter than the length of the channel structure 150 in the vertical direction. The second gate capping layer 161 is disposed between the back gate electrode 160 and the bit line BL. The third insulation pattern 173 is disposed on the back gate electrode 160. The second gate capping layer 161, the back gate electrode 160, and the third insulation pattern 173 overlap each other in the vertical direction.

The word line WL and the back gate electrode 160 may include a conductive material such as metal, metal nitride, metal silicide, polysilicon, conductive carbon, or a combination thereof. The first insulation pattern 171, the second insulation pattern 172, the third insulation pattern 173, the fourth insulation pattern 174, and the second gate capping layer 161 may include silicon oxide, silicon nitride, silicon oxynitride, silicon carbonitride, high-K dielectric, or a combination thereof.

A fourth insulation pattern 174 and a landing pad 175 are disposed on the channel structure 150, the second gate insulation layer 151, the third gate insulation layer 152, the second insulation pattern 172, and the third insulation pattern 173. The landing pad 175 may correspond to one channel structure 150. The landing pad 175 contacts the upper surface of the corresponding channel structure 150. The fourth insulation pattern 174 is disposed between the landing pads 175. The landing pad 175 may include a conductive material such as metal, metal nitride, metal silicide, polysilicon, conductive carbon, or a combination thereof. The fourth insulation pattern 174 may include silicon oxide, silicon nitride, silicon oxynitride, silicon carbonitride, high-K dielectric, or a combination thereof.

A bit line connection contact 183 is disposed on the bit line BL. One side of the bit line connection contact 183 contacts the upper surface of the bit line BL and extends in the vertical direction. The third line 124 and the fourth insulation pattern 174 may be disposed on the bit line connection contact 183. The third line 124 may be referred to as an upper line. The other side of the bit line connection contact 183 contacts the third line 124.

The contact plug 180 is disposed on the second line 123. One side of the contact plug 180 contacts the upper surface of the second line 123. The other side of the contact plug 180 is connected to the third line 124. The contact plug 180 extends in a vertical direction from the upper surface of the second line 123, penetrates the bonding insulation layer 130, the first insulation layer 140, the interlayer insulation layer 141, and the third insulation layer 193, and contacts the lower surface of the third line 124.

The bit line BL may be connected to the second line 123 through the bit line connection contact 183, the third line 124, and the contact plug 180. The second line 123 may be connected to the lower transistor TR1 through the third contact 128, the first line 122, and the first contact 116.

The bit line connection contact 183, the third line 124, and the contact plug 180 may include a conductive material such as metal, metal oxide, metal nitride, metal silicide, polysilicon, conductive carbon, or a combination thereof.

The capacitor 200 is disposed on the fourth insulation pattern 174 and the landing pad 175. The lower electrode 201 of the capacitor 200 may correspond to one landing pad 175. The lower electrode 201 contacts the upper surface of the landing pad 175. The dielectric layer 202 is disposed to cover the side surface and the upper surface of the lower electrode 201, and the upper surface of the fourth insulation pattern 174. In an embodiment, the dielectric layer 202 may conformally cover the side surface and the upper surface of the lower electrode 201. The upper electrode 203 is disposed on the dielectric layer 202. The lower electrode 201 and the upper electrode 203 may include a conductive material such as metal, metal oxide, metal nitride, metal silicide, polysilicon, conductive carbon, or a combination thereof. The dielectric layer 202 may include a high dielectric material, silicon oxide, silicon nitride, or a combination thereof.

A fourth contact 129 and a fifth insulation layer 195 are disposed on the upper electrode 203. A sixth line 126 is disposed on the fourth contact 129.

The fourth insulation layer 194 and the fourth contact 129 are disposed on the third line 124 and the fourth insulation pattern 174. The fourth contact 129 may penetrate the fourth insulation layer 194 to contact the upper surface of at least one third line 124. The fifth insulation layer 195 is disposed on the fourth insulation layer 194. The fifth line 125 is disposed in the fifth insulation layer 195.

Referring to FIGS. 3 and 4, the bit lines BL are disposed to be spaced apart from each other in the second direction SD. An interlayer insulation layer 141 is disposed between the bit lines BL in the second direction SD. The lower surface of the interlayer insulation layer 141 may form the same or substantially the same plane as the lower surface of the bit line BL.

The bit line BL may include a conductive layer BLc and a barrier layer BLb. The barrier layer BLb includes a horizontal barrier portion BLb1 and a vertical barrier portion BLb2.

The conductive layer BLc is spaced apart from the interlayer insulation layer 141 and the channel structure 150 with the barrier layer BLb disposed therebetween. The upper surface BLc1 and the side surface BLc2 of the conductive layer BLc contact the barrier layer BLb. The lower surface BLc3 of the conductive layer BLc contacts the first insulation layer 140. Hence, the barrier layer BLb covers the upper surface and the side surface of the conductive layer BLc. The barrier layer BLb may have a uniform or substantially uniform thickness along its entire span.

The barrier layer BLb surrounds the upper surface BLc1 and the side surface BLc2 of the conductive layer BLc. The barrier layer BLb may contact the entire side surface 141a of the interlayer insulation layer 141. The horizontal barrier portion BLb1 is disposed between the conductive layer BLc and the channel structure 150. The horizontal barrier portion BLb1 contacts the side surface 141a of the interlayer insulation layer 141.

The vertical barrier portion BLb2 is continuous to the horizontal barrier portion BLb1. The vertical barrier portion BLb2 is disposed between the conductive layer BLc and the interlayer insulation layer 141. The lower surface of the vertical barrier portion BLb2 may form the same or substantially the same plane as the lower surface BLc3 of the conductive layer BLc and the lower surface 141b of the interlayer insulation layer 141. The vertical barrier portion BLb2 contacts the side surface 141a of the interlayer insulation layer 141 and the side surface BLc2 of the conductive layer BLc. The vertical barrier portion BLb2 contacts an upper surface of the first insulation layer 140.

The conductive layer BLc may include a metal, metal nitride, metal oxide, metal silicide, polysilicon, conductive carbon, or a combination thereof. In an embodiment, the conductive layer BLc may include tungsten W. The tungsten may be in pure form or as tungsten silicide, tungsten carbide, or tungsten nitride.

The barrier layer BLb may include titanium (Ti), titanium nitride (TiN), tantalum (Ta), tantalum nitride (TaN), or a combination thereof.

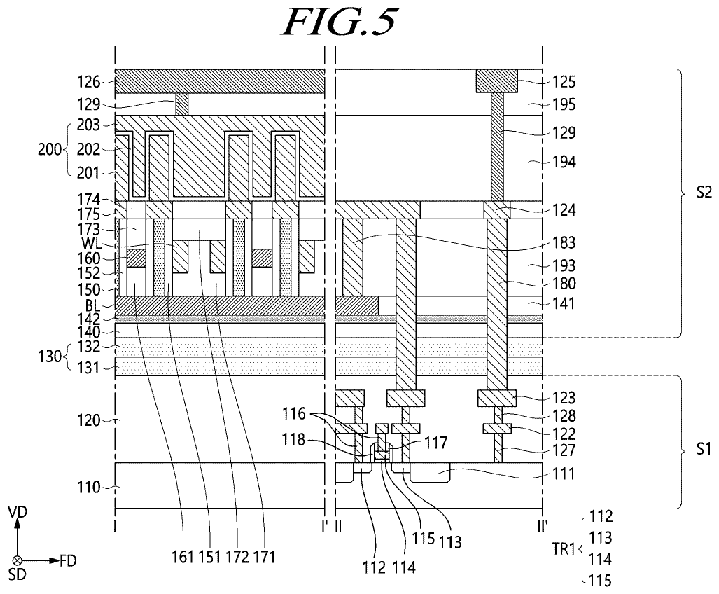

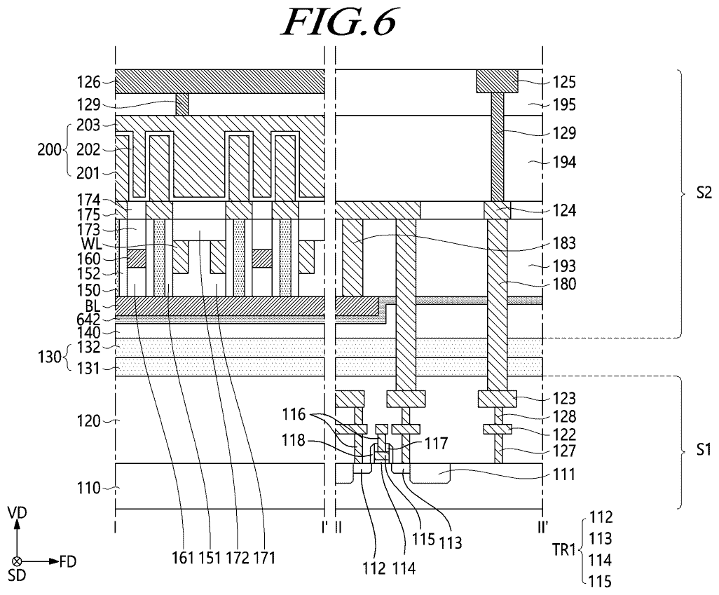

FIGS. 5 and 6 are views illustrating another cross-sectional structure of a memory device according to embodiments of the present disclosure.

Referring to FIG. 5, a second semiconductor structure S2 included in a memory device includes a second insulation layer 140, an interlayer insulation layer 141, a bit line BL, a channel structure 150, a second gate insulation layer 151, a third gate insulation layer 152, a back gate electrode 160, a second gate capping layer 161, a first insulation pattern 171, a second insulation pattern 172, a third insulation pattern 173, a fourth insulation pattern 174, a word line WL, a landing pad 175, lines 124, 125, and 126, a fourth contact 129, a third insulation layer 193, a fourth insulation layer 194, a fifth insulation layer 195, a capacitor 200, and a first bit line capping layer 142.

The bit line BL illustrated in FIG. 5 may be the same or substantially the same as the bit line BL described with reference to FIGS. 3 and 4.

The first bit line capping layer 142 is disposed between the bit line BL and the second insulation layer 140. The first bit line capping layer 142 may extend in the first direction FD and the second direction SD. The first bit line capping layer 142 may cover the entire lower surface of the bit line BL. In an embodiment, the first bit line capping layer 142 may include nitride.

Referring to FIG. 6, a second semiconductor structure S2 included in a memory device includes a second insulation layer 140, a bit line BL, a channel structure 150, a second gate insulation layer 151, a third gate insulation layer 152, a back gate electrode 160, a second gate capping layer 161, a first insulation pattern 171, a second insulation pattern 172, a third insulation pattern 173, a fourth insulation pattern 174, a word line WL, a landing pad 175, lines 124, 125, and 126 a fourth contact 129, a third insulation layer 193, a fourth insulation layer 194, a fifth insulation layer 195, a capacitor 200, and a second bit line capping layer 642.

The bit line BL illustrated in FIG. 6 may be the same or substantially the same as the bit line BL described with reference to FIGS. 3 and 4.

The second bit line capping layer 642 is disposed between the bit line BL and the second insulation layer 140. The second bit line capping layer 642 may extend in the first direction FD and the second direction SD. The second bit line capping layer 642 may cover the entire lower and side surfaces of the bit line BL. In an embodiment, the second bit line capping layer 642 may include nitride.

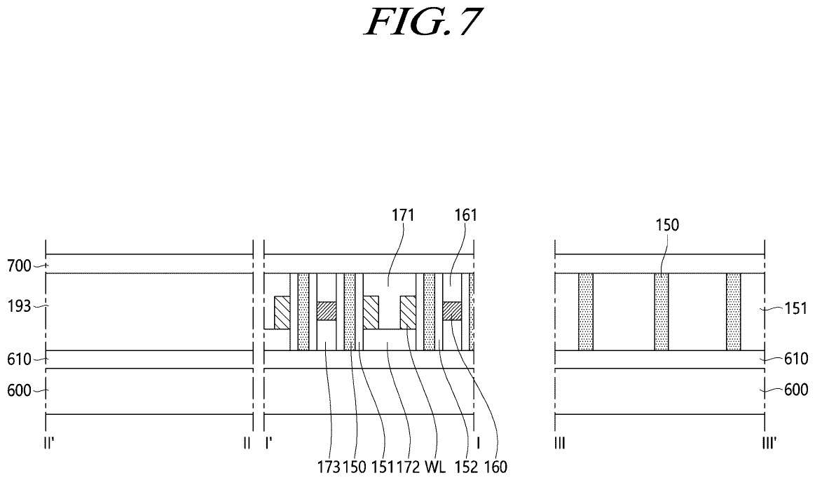

FIGS. 7 to 17 are views illustrating a method for forming a memory device according to embodiments of the present disclosure.

Referring to FIG. 7, the first substrate 600, the sixth insulation layer 610, the third insulation layer 193, the channel structure 150, the second gate insulation layer 151, the third gate insulation layer 152, the word line WL, the back gate electrode 160, the second gate capping layer 161, the first insulation pattern 171, the second insulation pattern 172, the third insulation pattern 173, and the interlayer insulation material layer 700 are prepared.

The interlayer insulation material layer 700 covers the channel structure 150, the second gate insulation layer 151, the third gate insulation layer 152, the first insulation pattern 171, and the second gate capping layer 161. In an embodiment, the interlayer insulation material layer 700 may include oxide.

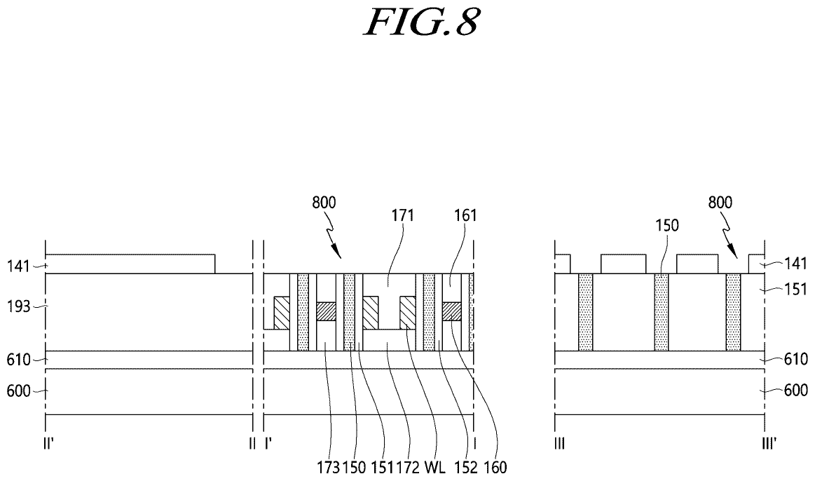

Referring to FIG. 8, a first hole 800 is formed in the interlayer insulation material layer 700. As the first hole 800 is formed, the interlayer insulation layer 141 is formed. The first hole 800 overlaps the channel structure 150. Referring to FIG. 2, the first hole 800 extends in the first direction FD. The first hole 800 may expose the channel structure 150. In an embodiment, the width of the first hole 800 in the second direction SD may be wider than the width of the channel structure 150 in the second direction SD.

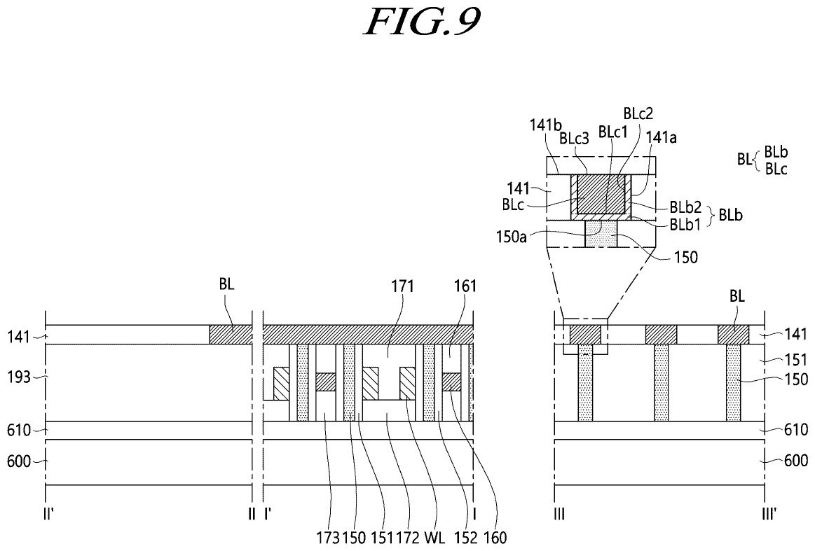

Referring to FIGS. 8 and 9, the barrier layer BLb of the bit line BL is formed in the first hole 800. The barrier layer BLb is formed on the side surface 141a of the interlayer insulation layer 141 and the channel structure 150. The process of forming the barrier layer BLb may include a process of depositing a conductive material and a process of removing a portion of the conductive material. For example, the barrier layer BLb may be formed by selectively removing only the conductive material deposited on the interlayer insulation layer 141 after the conductive material is deposited on the upper surface 141b of the interlayer insulation layer 141 and in the first hole 800.

The barrier layer BLb includes a horizontal barrier portion BLb1 and a vertical barrier portion BLb2. The upper surface of the vertical barrier portion BLb2 may form the same or substantially the same plane as the upper surface 141b of the interlayer insulation layer 141.

A conductive layer BLc is formed in a space between the vertical barrier portions BLb2. The side surface BLc2 of the conductive layer BLc contacts the vertical barrier portion BLb2. The conductive layer BLc contacts the upper surface of the horizontal barrier portion BLb1. The upper surface BLc3 of the conductive layer BLc may form the same or substantially the same plane as the upper surface of the vertical barrier portion BLb2 and the upper surface 141b of the interlayer insulation layer 141. The vertical barrier portion BLb2 contacts the side surface 141a of the interlayer insulation layer 141.

The conductive layer BLc may include a metal, metal nitride, metal oxide, metal silicide, polysilicon, conductive carbon, or a combination thereof. In an embodiment, the conductive layer BLc may include tungsten W.

The barrier layer BLb may include titanium (Ti), titanium nitride (TiN), tantalum (Ta), tantalum nitride (TaN), or a combination thereof.

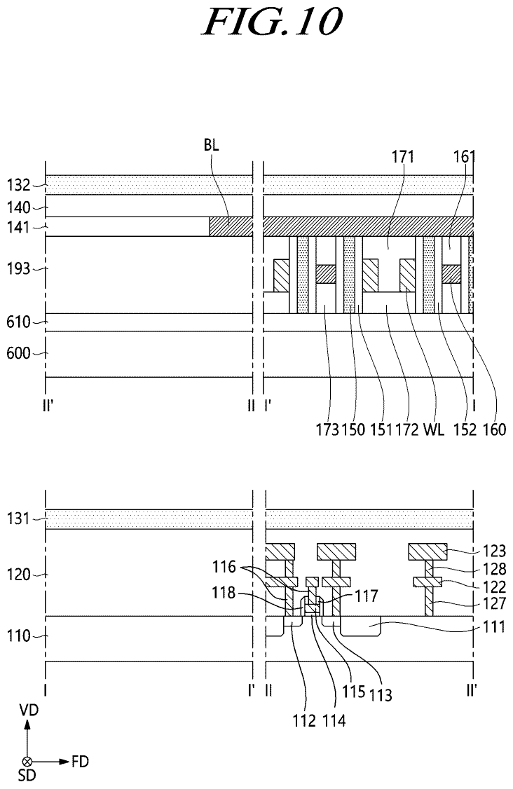

Referring to FIG. 10, a second insulation layer 140 is formed on the bit line BL and the interlayer insulation layer 141. A second bonding insulation layer 132 is formed on the second insulation layer 140. The first bonding insulation layer 131 is formed on the first insulation layer 120. The first bonding insulation layer 131 may include the same material as the material forming the second bonding insulation layer 132. In an embodiment, the first bonding insulation layer 131 and the second bonding insulation layer 132 may include silicon carbonitride.

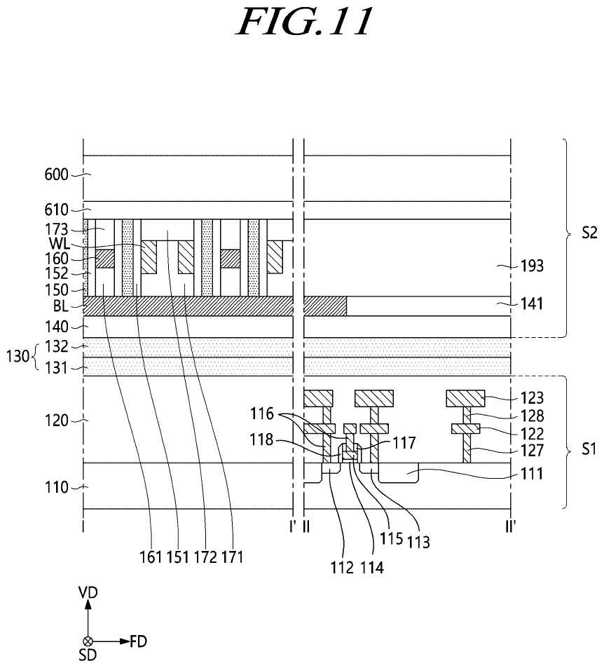

Referring to FIG. 11, the second bonding insulation layer 132 is bonded on the first bonding insulation layer 131. In an embodiment, the process of bonding the first semiconductor structure S1 and the second semiconductor structure S2 may include a process of applying heat after bringing the second bonding insulation layer 132 in contact with the upper surface of the first bonding insulation layer 131.

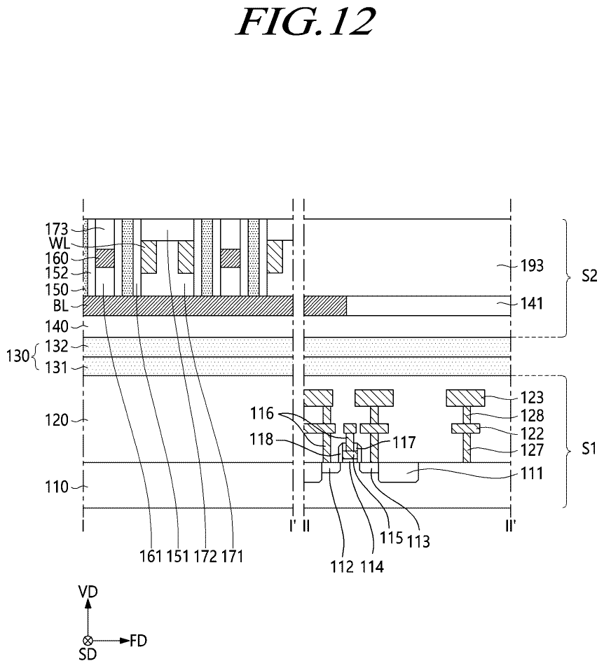

Referring to FIG. 12, the first substrate 600 and the sixth insulation layer 610 may be removed. In an embodiment, the first substrate 600 may be removed through a grinding process or a chemical mechanical polishing (CMP) process. In an embodiment, the sixth insulation layer 610 may be removed by a wet etching process.

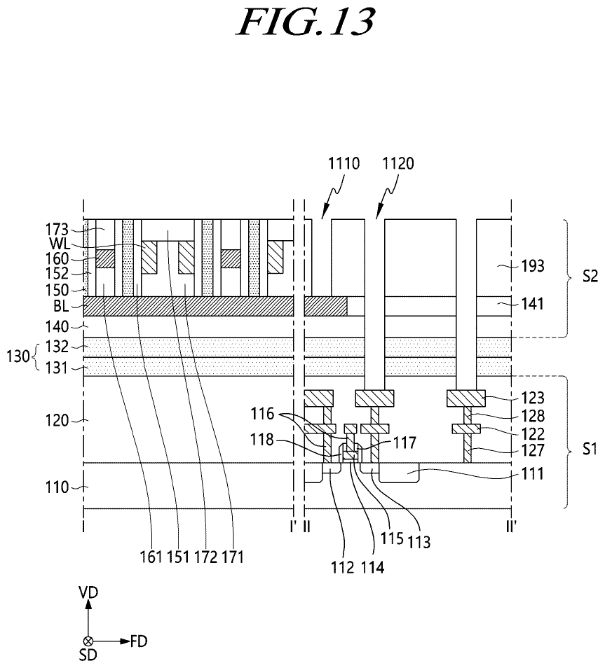

Referring to FIG. 13, a first through hole 1110 and a second through hole 1120 are formed. The first through hole 1110 may penetrate the third insulation layer 193 in the vertical direction to expose an upper surface of the bit line BL. The second through hole 1120 may penetrate the third insulation layer 193, the interlayer insulation layer 141, the second insulation layer 140, the bonding insulation layer 130, and the first insulation layer 120 in the vertical direction to expose the upper surface of the second line 123. The process of forming the first through hole 1110 and the second through hole 1120 may include an anisotropic etching process. The processes of forming the first through hole 1110 and the second through hole 1120 may be performed in the same process step.

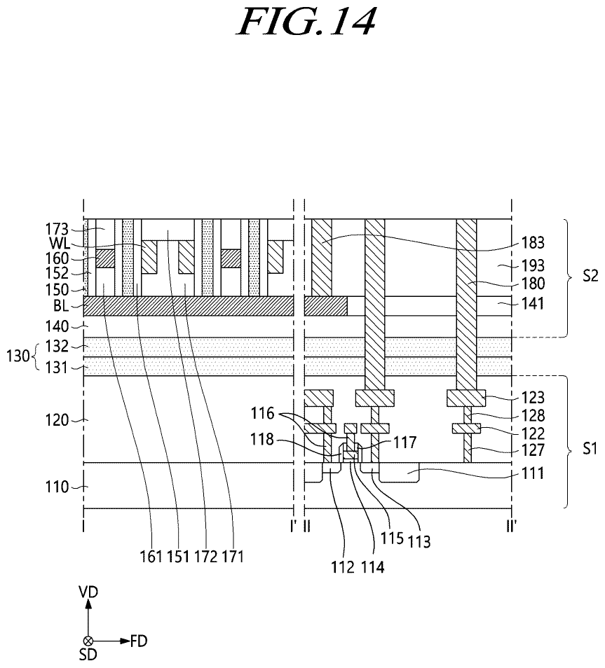

Referring to FIG. 14, the bit line connection contact 183 and the contact plug 180 are formed by filling the first through hole 1110 and the second through hole 1120 with a conductive material. The lower surface of the bit line connection contact 183 may contact the upper surface of the bit line BL. The lower surface of the contact plug 180 may contact the upper surface of the second line 123. The bit line connection contact 183 may include the same material as the material forming the contact plug 180.

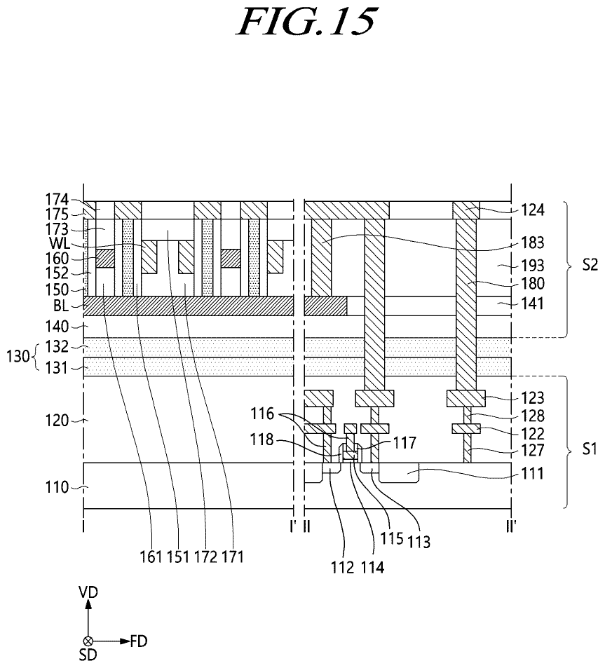

Referring to FIG. 15, a landing pad 175 is formed on the channel structure 150. A landing pad 175 may be formed on each of the channel structures 150. A third line 124 is formed on the bit line connection contact 183 and the contact plug 180. A fourth insulation pattern 174 is formed between the landing pads 175 and between the third lines 124. One landing pad 175 may correspond to one channel structure 150. The lower surface of the landing pad 175 contacts the upper surface of the corresponding channel structure 150. At least one third line 124 may connect the bit line connection contact 183 and the contact plug 180. The bit line BL may be connected to the second line 123 through the bit line connection contact 183, at least one third line 124 connected to the bit line connection contact 183, and the contact plug 180 connected to the at least one third line 124.

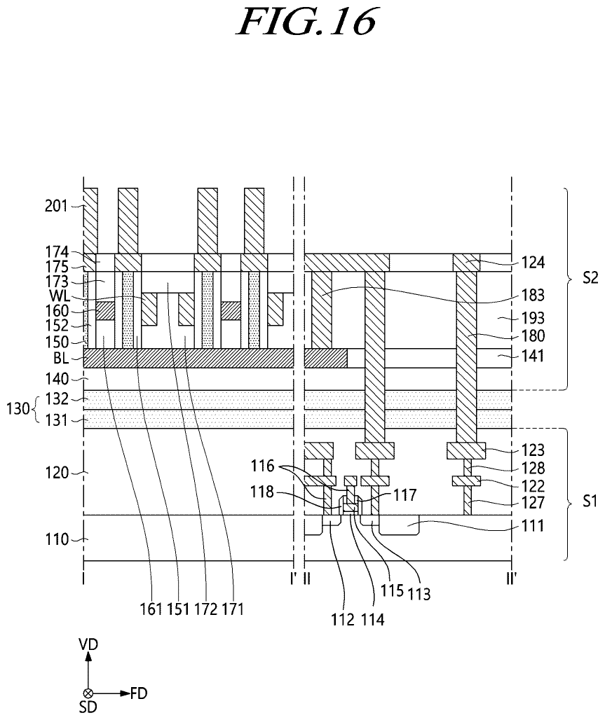

Referring to FIG. 16, the lower electrode 201 is formed on the landing pad 175. The lower electrode 201 may be formed on the upper surface of one corresponding landing pad 175. The lower surface of the lower electrode 201 contacts the upper surface of the landing pad 175. A plurality of spaced apart lower electrodes 201 may be formed, each having a pillar shape disposed on the upper surface of a corresponding landing pad 175.

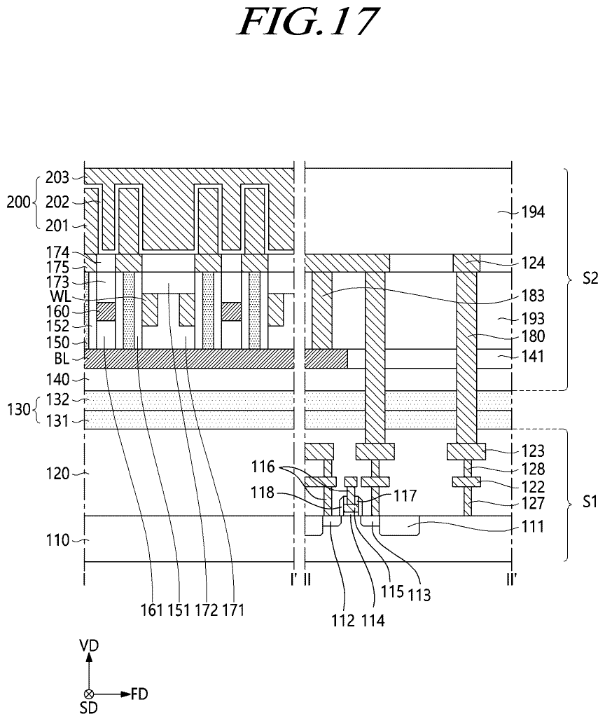

Referring to FIG. 17, a dielectric layer 202 is formed on the lower electrode 201 and the fourth insulation pattern 174. In an embodiment, the dielectric layer 202 may be conformally formed on the side surface and the upper surface of the lower electrode 201. The dielectric layer 202 covers the side surface and the upper surface of the lower electrode 201, and the upper surface of the fourth insulation pattern 174. The dielectric layer 202 may cover the side and upper surfaces of the plurality of the lower electrodes 201, and the upper surfaces of the fourth insulation pattern 174 which are disposed between the plurality of the lower electrodes 201. The upper electrode 203 is then formed on the dielectric layer 202. An upper surface of the upper electrode 203 may be above the upper surfaces of the lower electrode 201 and the dielectric layer 202.

Referring back to FIG. 2, a fifth insulation layer 195 is formed on the upper electrode 203 and the fourth insulation layer 194. After the fifth insulation layer 195 is formed, a fourth contact 129 penetrating the fifth insulation layer 195 is formed. The fourth contact 129 contacts the upper surface of the upper electrode 203 and the upper surface of the third line 124. A fourth line 125 and a fifth line 126 are formed on the fourth contact 129.

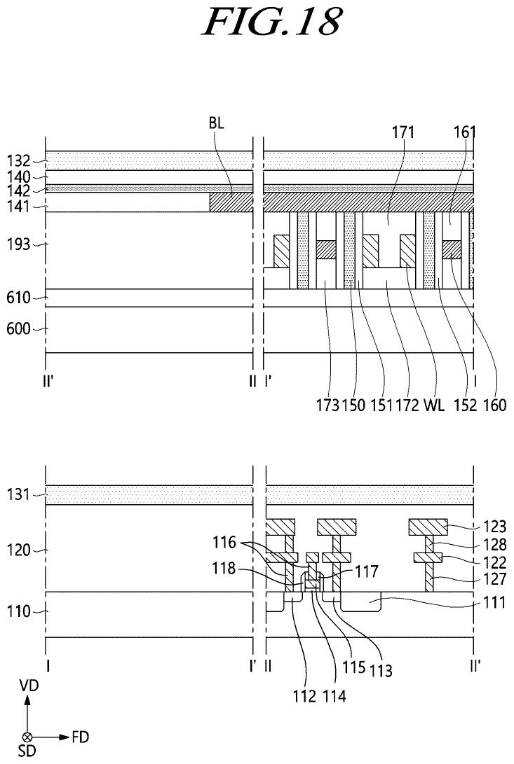

FIGS. 18 to 21 are views illustrating another method for forming a memory device according to embodiments of the present disclosure.

The memory device illustrated in FIG. 18 may be formed by the same method as the method for forming the memory device described with reference to FIGS. 7 to 9. For example, the interlayer insulation layer 141 exposing the channel structure 150 may be formed first, and then the conductive material may fill between the interlayer insulation layers 141 to form the bit line BL.

Referring to FIG. 18, the first bit line capping layer 142 is formed on the bit line BL and the interlayer insulation layer 141. The first bit line capping layer 142 covers an upper surface of the bit line BL. In an embodiment, the first bit line capping layer 142 may include nitride.

The second insulation layer 140 and the second bonding insulation layer 132 are then formed sequentially on the first bit line capping layer 142. The first bonding insulation layer 131 is formed on the first insulation layer 120.

Thereafter, a subsequent process of forming a memory device in the same or substantially the same manner as the method for forming the memory device described with reference to FIGS. 11 to 17 may be performed.

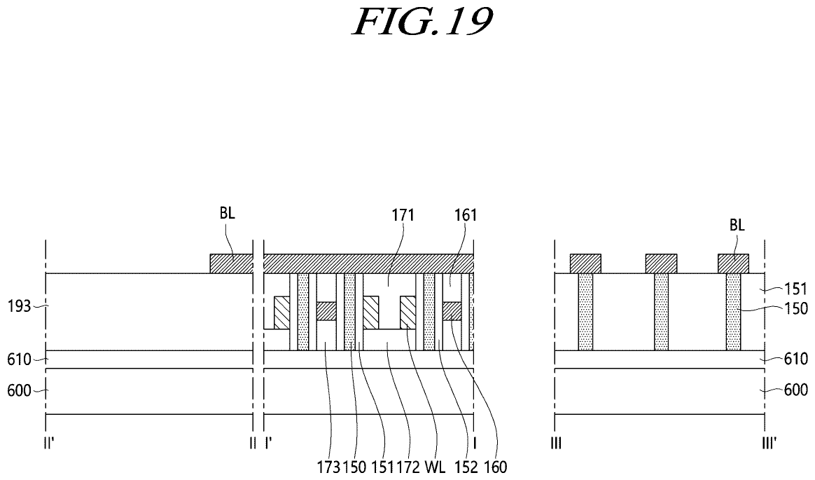

The memory device illustrated in FIG. 19 may be formed by the same method as the method for forming the memory device described with reference to FIGS. 7 to 9. For example, the interlayer insulation layer 141 exposing the channel structure 150 may be formed first, and then the conductive material may fill between the interlayer insulation layers 141 to form the bit line BL.

Referring to FIGS. 9 and 19, the interlayer insulation layer 141 may be removed. As the interlayer insulation layer 141 is removed, the upper surface and the side surface of the bit line BL, the upper surface of the third insulation layer 193, and the upper surface of the second gate insulation layer 151 may be exposed.

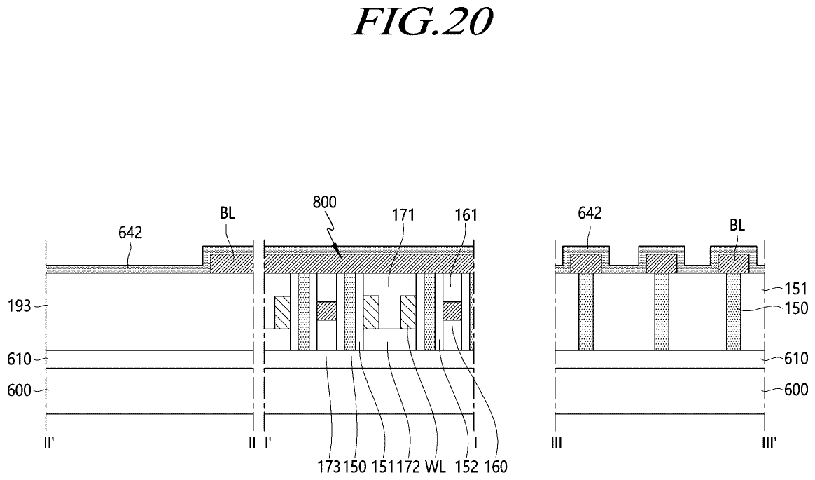

Referring to FIG. 20, the second bit line capping layer 642 covering the upper surface of the third insulation layer 193, the upper surface of the second gate insulation layer 151, and the upper surface and the side surface of the bit line BL is formed. In an embodiment, the second bit line capping layer 642 may include nitride.

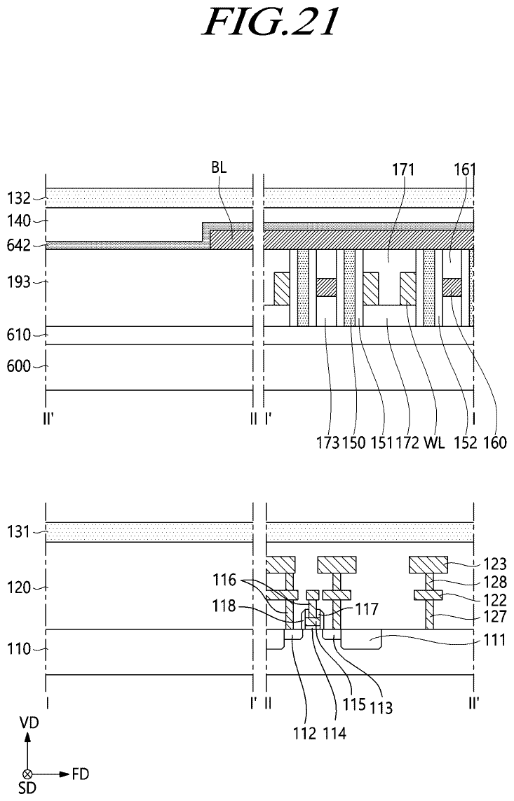

Referring to FIG. 21, the second insulation layer 140 and the second bonding insulation layer 132 are formed on the second bit line capping layer 642. The first bonding insulation layer 131 is formed on the first insulation layer 120.

Thereafter, a subsequent process of forming a memory device in the same or substantially the same manner as the method for forming the memory device described with reference to FIGS. 11 to 17 may be performed.

Referring back to FIGS. 4, 8, and 9, the interlayer insulation layer 141 is formed first, and then the bit line BL filling the space between the interlayer insulation layers 141 is formed. The bit line BL includes a conductive layer BLc and a barrier layer BLb. The barrier layer BLb surrounds the upper surface BLc1 and the side surface BLc2 of the conductive layer BLc. The conductive layer BLc is spaced apart from the interlayer insulation layer 141.

According to embodiments of the present disclosure, since the bit line BL is formed after the formation of the interlayer insulation layer 141, a short circuit between adjacent bit lines BLs may be prevented. This is described below in more detail. By contrast, when the bit line BL is formed before the interlayer insulation layer 141, a process of etching the bit line BL is required to form a space in which the interlayer insulation layer 141 is to be disposed. More specifically, when the process of etching the bit line BL is performed, the width of the bit line BL is very thin, and the bit line BL may be shaken or collapse. Accordingly, a short circuit between adjacent bit lines BL may occur. According to embodiments of the present disclosure, as the interlayer insulation layer 141 is first formed and then the bit line BL is formed in the space between the interlayer insulation layers 141, shaking or collapse of the bit line BL occurring in the bit line BL etching process may be prevented. Thus, a short circuit between adjacent bit lines BL may be prevented.

The above-described embodiments are merely illustrative, and it will be appreciated by one of ordinary skill in the art that various changes may be made thereto without departing from the scope of the present disclosure. Accordingly, the embodiments set forth herein are provided for illustrative purposes, and not to limit the scope of the present disclosure. Furthermore, the embodiments may be combined to form additional embodiments.

What is claimed is:

1. A memory device comprising:
a substrate having an upper surface;
bit lines disposed on the substrate;
an interlayer insulation layer disposed between the bit lines; and
channel structures respectively connected to the bit lines,
wherein the bit lines are extending in a first direction of the upper surface of the substrate,
wherein the bit lines are spaced apart from each other in a second direction of the upper surface of the substrate,
wherein each of the bit lines includes a conductive layer and a barrier layer surrounding a side surface and an upper surface of the conductive layer, and
wherein each of the channel structures is extending in a third direction perpendicular to the upper surface of the substrate.

2. The memory device of claim 1, wherein the conductive layer is spaced apart from the interlayer insulation layer in the second direction.

3. The memory device of claim 1, wherein the barrier layer is disposed between the conductive layer and the interlayer insulation layer.

4. The memory device of claim 1, wherein the barrier layer contacts an entire side surface of the interlayer insulation layer in the second direction.

5. The memory device of claim 1, wherein the barrier layer includes a horizontal barrier portion contacting a lower surface of each of the channel structures and a vertical barrier portion disposed between the conductive layer and the interlayer insulation layer.

6. The memory device of claim 5, wherein the vertical barrier portion contacts a side surface of the conductive layer and a side surface of the interlayer insulation layer.

7. The memory device of claim 5, wherein a lower surface of the vertical barrier portion forms the same or substantially the same plane as a lower surface of the conductive layer.

8. The memory device of claim 5, wherein a lower surface of the vertical barrier portion forms the same or substantially the same plane as a lower surface of the interlayer insulation layer.

9. The memory device of claim 1, wherein the conductive layer includes tungsten, and the barrier layer includes titanium nitride.

10. A memory device comprising:
a first semiconductor structure; and
a bonding insulation layer disposed on the first semiconductor structure; and
a second semiconductor structure disposed on the bonding insulation layer,
wherein the second semiconductor structure includes bit lines extending in a first direction of an upper surface of the first semiconductor structure, the bit lines being spaced apart from each other in a second direction of the upper surface of the first semiconductor structure, and
wherein the bit lines include a conductive layer and a barrier layer surrounding a side surface and an upper surface of the conductive layer.

11. The memory device of claim 10, wherein an interlayer insulation layer is disposed between the bit lines and spaced apart from the conductive layer in the second direction, and
wherein the second semiconductor structure further includes channel structures respectively connected to the bit lines, the channel structures extending in a third direction perpendicular to the upper surface of the first semiconductor structure.

12. The memory device of claim 11, wherein the barrier layer contacts a lower surface of each of the channel structures.

13. The memory device of claim 10, wherein the barrier layer is disposed between the conductive layer and the interlayer insulation layer.

14. The memory device of claim 10, wherein the barrier layer contacts an entire side surface of the interlayer insulation layer in the second direction.

15. The memory device of claim 10, wherein the barrier layer includes a horizontal barrier portion positioned on the conductive layer and a vertical barrier portion disposed between the conductive layer and the interlayer insulation layer, and
wherein the vertical barrier portion contacts a side surface of the conductive layer and a side surface of the interlayer insulation layer.

16. The memory device of claim 15, wherein a lower surface of the vertical barrier portion forms the same or substantially the same plane as a lower surface of the conductive layer.

17. The memory device of claim 15, wherein a lower surface of the vertical barrier portion forms the same or substantially the same plane as a lower surface of the interlayer insulation layer.

18. A method for manufacturing a memory device, the method comprising:
forming, on a first substrate, a channel structure extending in a direction perpendicular to the first substrate;
forming an interlayer insulation material layer on the channel structure;
forming first holes in the interlayer insulation material layer in an area overlapping the channel structure; and
forming bit lines in the first holes.

19. The method of claim 18, wherein each of the bit lines includes a conductive layer and a barrier layer surrounding a side surface and an upper surface of the conductive layer.

20. The method of claim 19, wherein the conductive layer is spaced apart from the interlayer insulation material layer.
